(19) United States
(12) Patent Application Publication
(10) Pub. No.: US 2010/0123512 A1
(43) Pub. Date: May 20, 2010

(54) Booster circuit

(76) Inventors: Yasushi Imai, Chiba-shi (JP); Tomohiro Oka, Chiba-shi (JP)

Correspondence Address: BRUCE L. ADAMS, ESQ;ADAMS & WILKS, SUITE 1231, 17 BATTERY PLACE, NEW YORK, NY, 10004, US

(21) Appl. No.: 12/590,950

(22) Filed: Nov. 17, 2009

(30) Foreign Application Priority Data
Nov. 19, 2008 (JP) 2008-295297

(51) Int. Cl. G11C 5/14; H02M 3/07

(52) U.S. Cl. 327/530; 327/589

(57) ABSTRACT

Provided is a booster circuit capable of shortening a boost rise time. A PMOS transistor is provided, as a switch circuit for controlling an operation of the booster circuit, between a boosted voltage output terminal and a voltage divider circuit in the booster circuit, and the PMOS transistor has a gate connected to a power supply terminal and a source and a back gate connected to the boosted voltage output terminal. Therefore, the PMOS transistor is turned off immediately after a start of a boosting operation, and hence an inverting input terminal of a comparator circuit is pulled down. Accordingly, the comparator circuit outputs a boosting operation signal, and the booster circuit immediately starts the boosting operation, with the result that the boost rise time may be shortened.

### BACKGROUND OF THE INVENTION

1. Field of the Invention

The present invention relates to a booster circuit.

2. Description of the Related Art

Description is made of a conventional booster circuit. FIG. 2 is a circuit diagram illustrating the conventional booster circuit.

If a signal EW becomes a high signal, an NMOS transistor 55 is turned on. Then, based on a reference voltage VREF and a divided voltage VFB that is based on a boosted voltage VPP and a ground voltage VSS, a comparator circuit 52 operates so as to boost a power supply voltage VCC. If the divided voltage VFB is lower than the reference voltage VREF, the comparator circuit 52 outputs a high signal, and a booster 54 inputs a pulse signal CLK via an AND circuit 53. As a result, the booster 54 boosts the power supply voltage VCC. If the divided voltage VFB is higher than the reference voltage VREF, the comparator circuit 52 outputs a low signal, and the low signal inputs to the booster 54 by the AND circuit 53. As a result, the booster 54 does not boost the power supply voltage VCC.

If the signal EW becomes a low signal, voltages of a gate, a source, and a back gate of the NMOS transistor 55 become equal to the ground voltage VSS, and hence the NMOS transistor 55 is turned off. As a result, a current is not allowed to flow through a path including a boosted voltage output terminal, a voltage divider circuit 51, the NMOS transistor 55, and a ground terminal. At this time, an inverting input terminal of the comparator circuit 52 is pulled up by the voltage divider circuit 51. Further, the AND circuit 53 inputs a low signal to the booster 54 (see, for example, JP 2008-011635 A (FIGS. 6 and 7)).

However, immediately after the start of a boosting operation, the inverting input terminal of the comparator circuit 52 is pulled up by the voltage divider circuit 51, and hence the divided voltage VFB becomes higher than the reference voltage VREF. As a result, the comparator circuit 52 outputs a low signal, and the AND circuit 53 inputs the low signal to the booster 54. In other words, immediately after the start of the boosting operation, the booster 54 does not start boosting the power supply voltage VCC as otherwise expected. Accordingly, a boost rise time is unnecessarily elongated.

### SUMMARY OF THE INVENTION

The present invention has been made in view of the above-mentioned problem, and an object of the present invention is therefore to provide a booster circuit capable of shortening a boost rise time.

In order to solve the above-mentioned problem, the present invention provides a booster circuit including: a voltage divider circuit for outputting a divided voltage determined by dividing a boosted voltage; a comparator circuit for comparing the input divided voltage and a reference voltage; a booster for boosting the power supply voltage according to an output signal of the comparator circuit to output the boosted voltage to a boosted voltage output terminal; and a switch that is provided between the boosted voltage output terminal and the voltage divider circuit and is turned on if the boosted voltage is higher than a predetermined voltage.

In the booster circuit according to the present invention, a PMOS transistor 11 is turned off immediately after the start of a boosting operation, and hence an inverting input terminal of a comparator circuit 13 is pulled down by a voltage divider circuit 12. Accordingly, the comparator circuit 13 outputs a boosting operation signal, and the booster circuit immediately starts the boosting operation, with the result that the boost rise time may be shortened.

### BRIEF DESCRIPTION OF THE DRAWINGS

In the accompanying drawings:

FIG. 1 is a circuit diagram illustrating a booster circuit according to the present invention; and

FIG. 2 is a circuit diagram illustrating a conventional booster circuit.

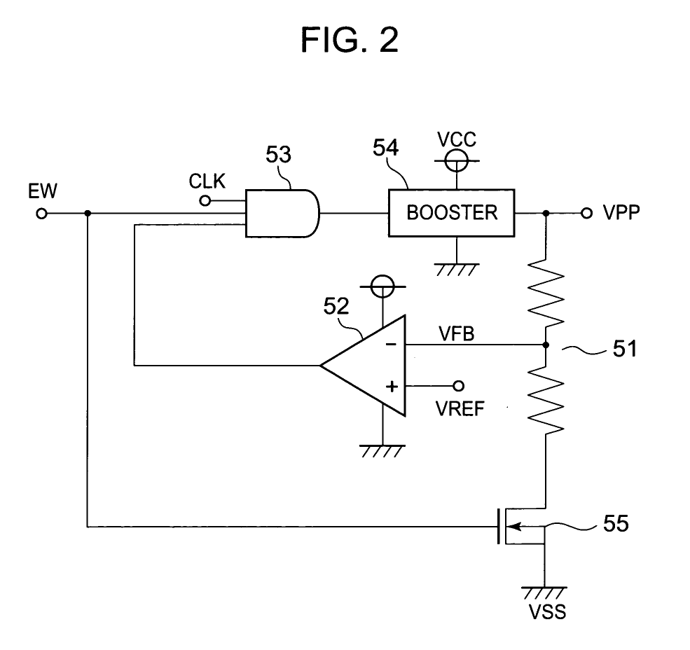

### DETAILED DESCRIPTION OF THE PREFERRED EMBODIMENT

Hereinafter, an embodiment of the present invention is described with reference to the accompanying drawing.

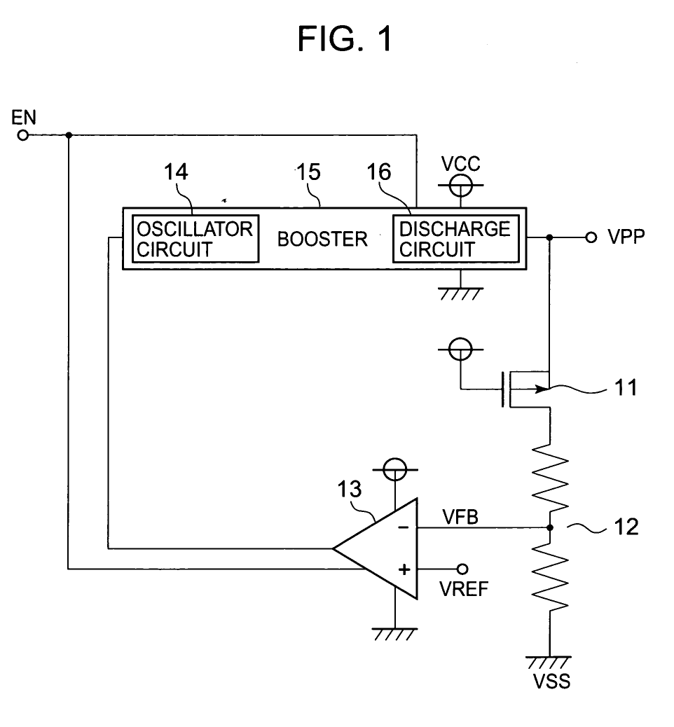

First, a structure of a booster circuit is described. FIG. 1 is a circuit diagram illustrating a booster circuit according to the present invention.

The booster circuit according to the present invention includes a PMOS transistor 11, a voltage divider circuit 12, a comparator circuit 13, and a booster 15. The booster 15 includes an oscillator circuit 14 and a discharge circuit 16.

The PMOS transistor 11 has a gate connected to a power supply terminal, a source and a back gate connected to a boosted voltage output terminal, and a drain connected to an input terminal of the voltage divider circuit 12. The voltage divider circuit 12 is provided between the drain of the PMOS transistor 11 and a ground terminal. The comparator circuit 13 is provided between the power supply terminal and the ground terminal, and has a non-inverting input terminal connected to a reference voltage terminal, an inverting input terminal connected to an output terminal of the voltage divider circuit 12, an output terminal connected to an input terminal of the booster 15, and a control terminal connected to an enable terminal. The booster 15 is provided between the power supply terminal and the ground terminal, and has an output terminal connected to the boosted voltage output terminal and a control terminal connected to the enable terminal. The oscillator circuit 14 is provided between the power supply terminal and the ground terminal, and has an input terminal connected to the output terminal of the comparator circuit 13 and a control terminal connected to the enable terminal. The discharge circuit 16 is provided between the power supply terminal and the ground terminal, and has an output terminal connected to the boosted voltage output terminal and a control terminal connected to the enable terminal.

The booster circuit according to the present invention boosts a power supply voltage VCC of the power supply terminal to output a boosted voltage VPP from the boosted voltage output terminal. The voltage divider circuit 12 divides the boosted voltage VPP to output a divided voltage VFB. The PMOS transistor 11 has the gate connected to the power supply terminal and the source and the back gate connected to the boosted voltage output terminal. Therefore, if the boosted voltage VPP is higher than a voltage determined by adding the power supply voltage VCC and an absolute value of a threshold voltage of the PMOS transistor 11, the PMOS transistor 11 is turned on. The comparator circuit 13 compares the divided voltage VFB and a reference voltage VREF to output a high signal if the divided voltage VFB is lower than the reference voltage VREF and to output a low signal if the divided voltage VFB is higher than the reference voltage VREF. The oscillator circuit 14 oscillates if the output signal of the comparator circuit 13 is the high signal, to output a pulse signal, and does not oscillate if the output signal of the comparator circuit 13 is the low signal. The booster 15 boosts the power supply voltage VCC based on the pulse signal from the oscillator circuit 14, to output the boosted voltage VPP. The discharge circuit 16 discharges the boosted voltage output terminal based on a signal EN from the boosted voltage VPP to the power supply voltage VCC.

The booster 15 is a circuit for boosting the power supply voltage VCC and includes, for example, a charge pump circuit. The oscillator circuit 14 is a circuit for outputting a pulse signal and includes, for example, a ring oscillator circuit, a CR oscillator circuit, or a crystal oscillator circuit.

Next, an operation of the booster circuit according to the present invention is described.

If the signal EN becomes a high signal, the comparator circuit 13, the oscillator circuit 14, and the booster 15 start a boosting operation. At this time, based on the reference voltage VREF and the divided voltage VFB which is based on the boosted voltage VPP and a ground voltage VSS, the comparator circuit 13 operates so as to boost the power supply voltage VCC. If the divided voltage VFB is lower than the reference voltage VREF, the comparator circuit 13 outputs a high signal, and the oscillator circuit 14 oscillates to output a pulse signal. As a result, the booster 15 boosts the power supply voltage VCC. If the divided voltage VFB is higher than the reference voltage VREF, the comparator circuit 13 outputs a low signal, and therefore the oscillator circuit 14 does not oscillate. As a result, the booster 15 does not boost the power supply voltage VCC.

Before the boosting operation, the boosted voltage VPP is equal to the power supply voltage VCC by the operation of the discharge circuit 16. In this case, voltages of the gate, the source, and the back gate of the PMOS transistor 11 are equal to the power supply voltage VCC, and hence the PMOS transistor 11 is in an off-state. Therefore, the inverting input terminal of the comparator circuit 13 is pulled down by the voltage divider circuit 12. At this time, immediately after the start of the boosting operation, the reference voltage VREF is input to the non-inverting input terminal of the comparator circuit 13 and the ground voltage VSS is input to the inverting input terminal thereof, with the result that a high signal is output from the output terminal thereof. Owing to that high signal, the oscillator circuit 14 starts oscillating immediately after the start of the boosting operation to output a pulse signal. Then, upon reception of that pulse signal, the booster 15 immediately starts boosting the power supply voltage VCC.

If the signal EN becomes a low signal, the discharge circuit 16 discharges the boosted voltage VPP to be equal to the power supply voltage VCC. In this case, the voltages of the gate, the source, and the back gate of the PMOS transistor 11 become equal to the power supply voltage VCC, and hence the PMOS transistor 11 is turned off. Therefore, a current is not allowed to flow through a path including the boosted voltage output terminal, the PMOS transistor 11, the voltage divider circuit 12, and the ground terminal. At this time, the inverting input terminal of the comparator circuit 13 is pulled down by the voltage divider circuit 12. Further, the comparator circuit 13, the oscillator circuit 14, and the booster 15 stop operating.

With the circuit structure described above, the PMOS transistor 11 is turned off immediately after the start of the boosting operation, and hence the inverting input terminal of the comparator circuit 13 is pulled down by the voltage divider circuit 12. Accordingly, the comparator circuit 13 outputs a boosting operation signal, and the booster circuit immediately starts the boosting operation, with the result that a boost rise time may be shortened.

Moreover, control wiring for controlling the gate of the PMOS transistor 11 is unnecessary, and hence the circuit area becomes smaller correspondingly. Further, the number of noise sources is reduced.

It should be noted that if the divided voltage VFB is lower than the reference voltage VREF, the comparator circuit 13 outputs a high signal, and if the output signal of the comparator circuit 13 is the high signal, the oscillator circuit 14 oscillates. Alternatively, if the divided voltage VFB is lower than the reference voltage VREF, the comparator circuit 13 may output a low signal, and if the output signal of the comparator circuit 13 is the low signal, the oscillator circuit 14 may oscillate.

Further, if the signal EN becomes a low signal, the comparator circuit 13, the oscillator circuit 14, and the booster 15 stop the boosting operating. Alternatively, if the signal EN becomes a high signal, the comparator circuit 13, the oscillator circuit 14, and the booster 15 may stop the boosting operating.

What is claimed is:

1. A booster circuit for outputting a boosted voltage determined by boosting a power supply voltage from a boosted voltage output terminal, comprising:
a voltage divider circuit for outputting a divided voltage determined by dividing the boosted voltage;
a comparator circuit for inputting the divided voltage and a reference voltage to compare the divided voltage and the reference voltage;
a booster for inputting an output signal of the comparator circuit and boosting the power supply voltage according to the output signal to output the boosted voltage to the boosted voltage output terminal; and
a switch provided between the boosted voltage output terminal and the voltage divider circuit, which is configured to be turned on if the boosted voltage is higher than a predetermined voltage.

2. A booster circuit according to claim 1, wherein:
the switch comprises a MOS transistor; and
the predetermined voltage comprises a voltage determined by adding the power supply voltage and an absolute value of a threshold voltage of the MOS transistor.

3. A booster circuit according to claim 2, further comprising a discharge circuit,
wherein the discharge circuit discharges the boosted voltage output terminal from the boosted voltage to the power supply voltage.
